(19) United States
(12) Patent Application Publication
(10) Pub. No.: US 2023/0301065 A1
(43) Pub. Date: Sep. 21, 2023

(54) SEMICONDUCTOR MEMORY DEVICE AND METHOD OF PRODUCING THE SAME

(71) Applicant: Kioxia Corporation, Tokyo (JP)

(72) Inventors: Mutsumi OKAJIMA, Yokkaichi Mie (JP); Keiji IKEDA, Kawasaki Kanagawa (JP)

(73) Assignee: Kioxia Corporation, Tokyo (JP)

(21) Appl. No.: 17/901,077

(22) Filed: Sep. 1, 2022

(30) Foreign Application Priority Data
Mar. 16, 2022 (JP) 2022-041701

(51) Int. Cl. H01L 27/108; G11C 11/4091

(52) U.S. Cl. CPC H01L 27/10811; G11C 11/4091; H01L 27/10873

(57) ABSTRACT

A semiconductor memory device includes: a plate electrode; a plurality of memory capacitors arranged along a front surface of the plate electrode; and a plurality of memory transistors electrically connected to the plurality of memory capacitors. Each memory capacitor includes: a columnar first electrode electrically connected to the memory transistor; a dielectric layer provided on an outer periphery of the first electrode; a second electrode provided on an outer periphery of the dielectric layer and electrically connected to the plate electrode; and an insulating layer provided between the first electrode and the plate electrode and containing a material that is different from a material contained in the dielectric layer.

### CROSS-REFERENCE TO RELATED APPLICATION(S)

This application is based upon and claims the benefit of priority from Japanese Patent Application No. 2022-041701, filed Mar. 16, 2022, the entire contents of which are incorporated herein by reference.

### FIELD

Embodiments described herein relate generally to a semiconductor memory device and a method of producing the semiconductor memory device.

### BACKGROUND

A semiconductor memory device configured as dynamic random access memory (DRAM) includes a plurality of memory cells, each being configured with a transistor and a capacitor used in combination.

### DESCRIPTION OF THE DRAWINGS

FIG. 1 is an equivalent circuit diagram showing the configuration of a memory cell.

FIG. 2 is a sectional view showing the configuration of a semiconductor memory device according to at least one embodiment.

FIG. 3 is a sectional view showing the configuration of the semiconductor memory device according to in at least one embodiment.

FIG. 4 is a diagram illustrating a method of producing the semiconductor memory device.

FIG. 5 is a diagram illustrating the method of producing the semiconductor memory device.

FIG. 6 is a diagram illustrating the method of producing the semiconductor memory device.

FIG. 7 is a diagram illustrating the method of producing the semiconductor memory device.

FIG. 8 is a diagram illustrating the method of producing the semiconductor memory device.

FIG. 9 is a diagram illustrating the method of producing the semiconductor memory device.

FIG. 10 is a diagram illustrating the method of producing the semiconductor memory device.

FIG. 11 is a diagram illustrating the method of producing the semiconductor memory device.

FIG. 12 is a diagram illustrating the method of producing the semiconductor memory device.

FIG. 13 is a diagram illustrating the method of producing the semiconductor memory device.

FIG. 14 is a diagram illustrating the method of producing the semiconductor memory device.

FIG. 15 is a diagram illustrating the method of producing the semiconductor memory device.

FIG. 16 is a diagram illustrating the method of producing the semiconductor memory device.

FIG. 17 is a diagram illustrating the method of producing the semiconductor memory device.

FIG. 18 is a diagram illustrating the method of producing the semiconductor memory device.

FIG. 19 is a sectional view showing the configuration of a semiconductor memory device according to a comparative example.

### DETAILED DESCRIPTION

At least one embodiment provides a semiconductor memory device that is easily miniaturized and a method of producing the semiconductor memory device.

In general, according to one embodiment, a semiconductor memory device includes: a conductor layer extending along a plane including a first direction and a second direction crossing the first direction; a plurality of capacitors arranged along a front surface of the conductor layer; and a plurality of transistors electrically connected to the plurality of capacitors. Each capacitor includes: a columnar first electrode extending in a third direction crossing each of the first direction and the second direction and electrically connected to one of the plurality of transistors; a dielectric layer provided on an outer periphery of the first electrode; a second electrode provided on an outer periphery of the dielectric layer and electrically connected to the conductor layer; and an insulating layer provided between the first electrode and the conductor layer and containing a material that is different from a material contained in the dielectric layer.

According to at least one other embodiment, a method of producing a semiconductor memory device includes: forming a first sacrifice layer on a front surface of a first substrate; forming, in the first sacrifice layer, a columnar hole reaching the first substrate; forming a second sacrifice layer in a bottom of the columnar hole; forming a first electrode in the columnar hole in which the second sacrifice layer is formed; exposing the first electrode and the second sacrifice layer by removing the first sacrifice layer; forming a dielectric layer covering an outside of the first electrode and the second sacrifice layer; forming a second electrode covering an outside of the dielectric layer; forming a transistor that is electrically connected to the first electrode; removing the first substrate and the second sacrifice layer; forming a first insulating layer in a portion where the second sacrifice layer was formed; exposing the second electrode around the first insulating layer; and forming a conductor layer that covers the first insulating layer and is electrically connected to the second electrode.

Hereinafter, the at least one embodiment will be described with reference to the accompanying drawings. In order to facilitate the understanding of the description, the same element is denoted by the same reference sign as much as possible in the drawings and overlapping explanations are omitted.

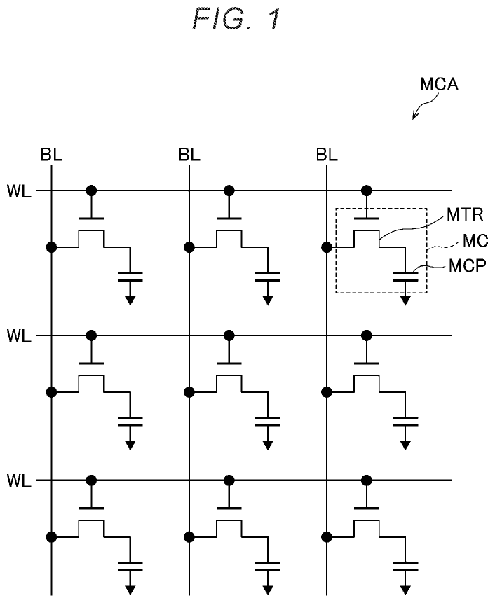

A semiconductor memory device 10 according to the present embodiment is a volatile memory device configured as what is called “dynamic random access memory (DRAM)”. The semiconductor memory device 10 includes a memory cell array MCA for storing data. As shown in an equivalent circuit diagram of FIG. 1, the memory cell array MCA includes a plurality of memory cells MC, each being configured with a memory transistor MTR and a memory capacitor MCP used in combination.

A plurality of bit lines BL and a plurality of word lines WL are provided in the memory cell array MCA. The plurality of bit lines BL each extend in a first direction (an up-and-down direction in FIG. 1) and are arranged in such a way as to be parallel to each other. The plurality of word lines WL each extend in a second direction (a right-and-left direction in FIG. 1) perpendicular to the first direction and are arranged in such a way as to be parallel to each other. The memory cell MC is placed at each intersection of the bit line BL and the word line WL.

The memory transistor MTR performs a switching operation between the bit line BL and the memory capacitor MCP, which will be described below, and is configured as a semiconductor transistor in at least one embodiment. One of the source and the drain of the memory transistor MTR is connected to the bit line BL and the other is connected to the memory capacitor MCP. The gate of the memory transistor MTR is connected to the word line WL. By performing an opening and closing operation based on the potential of the word line WL, the memory transistor MTR switches between a state in which the bit line BL and the memory capacitor MCP are electrically connected and a state in which the bit line BL and the memory capacitor MCP are electrically interrupted.

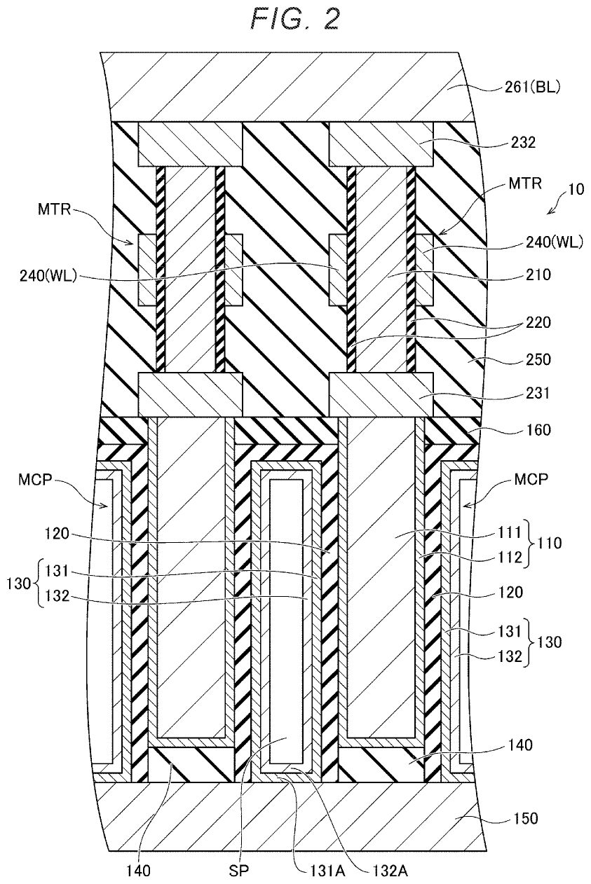

The memory capacitor MCP is a portion that holds data by storing electric charge. One end of the memory capacitor MCP is connected to one of the source and the drain of the memory transistor MTR and the other end is connected to a plate electrode 150 (see FIG. 2) which is not shown in FIG. 1. As will be described later, the ends of the plurality of memory capacitors MCP are common-connected to the plate electrode 150.

The specific configuration of the memory cell MC and an area surrounding it will be described with reference to FIG. 2. FIG. 2 schematically depicts a cross section of each of two memory transistors MTR connecting to one bit line BL and two memory capacitors MCP electrically connected to the memory transistors MTR from below. In FIG. 2, a wiring layer 261, which is a bit line BL, extends in a right-and-left direction. This direction corresponds to a “first direction” in at least one embodiment. Moreover, in FIG. 2, a wiring 240, which is a word line WL, extends in a depth direction with respect to the surface of paper. This direction is a direction crossing the above-described first direction and corresponds to a “second direction” in at least one embodiment.

First, the configuration of the memory transistor MTR will be described. The memory transistor MTR includes a channel layer 210 and a gate insulating film 220.

The channel layer 210 is formed of a material containing an oxide semiconductor such as a metal oxide and is an approximately circular cylindrical layer extending in an up-and-down direction of FIG. 2. An oxide containing at least one element selected from In, Ga, Al, Zn, and Ti, for example, may be used as the oxide semiconductor. The lower end of the channel layer 210 is connected to the upper end of the memory capacitor MCP with a conductive layer 231 placed therebetween. The upper end of the channel layer 210 is connected to the wiring layer 261 with a conductive layer 232 placed therebetween. The wiring layer 261 extends in the right-and-left direction of FIG. 2 and is one of a plurality of layers formed of metal in such a way as to be arranged in the depth direction with respect to the surface of paper of FIG. 2. Each wiring layer 261 corresponds to the bit line BL shown in FIG. 1.

The gate insulating film 220 is a film formed of an insulating material such as an oxide or oxynitride and is formed in such a way as to cover the entire external surface of the channel layer 210.

The channel layer 210 and the gate insulating film 220 vertically pass through the wiring 240. That is, the entire periphery of a part of the gate insulating film 220 is covered with the wiring 240 from the outside. The wiring 240 extends in the depth direction with respect to the surface of paper of FIG. 2 and is one of a plurality of layers formed of metal in such a way as to be arranged in the right-and-left direction of FIG. 2. The two gate insulating films 220 shown in FIG. 2 pass through different wirings 240. Each wiring 240 corresponds to the word line WL shown in FIG. 1.

Switching between a conductive state in which a channel is formed in the channel layer 210 and an interrupted state in which the channel disappears from the channel layer 210 is performed in accordance with the potential of the wiring 240 (the word line WL).

The periphery of each memory transistor MTR is covered with an insulator layer 250 such as silicon oxide.

The configuration of the memory capacitor MCP will be described with reference to FIG. 2. The memory capacitor MCP includes a first electrode 110, a dielectric layer 120, and a second electrode 130. The first electrode 110, the second electrode 130, and the dielectric layer 120 placed therebetween of the memory capacitor MCP constitute a capacitor.

The first electrode 110 is an approximately circular cylindrical electrode extending in the up-and-down direction of FIG. 2. The direction in which the first electrode 110 extends is a direction crossing each of the above-mentioned first and second directions and corresponds to a “third direction” in at least one embodiment. The cross-sectional shape of the first electrode 110 observed when the first electrode 110 is cut perpendicularly to the longitudinal direction thereof, that is, the shape of a cross section of the first electrode 110 perpendicular to the third direction is circular. The size (diameter) of the cross-sectional shape may differ depending on the position at which the first electrode 110 is cut. The upper end of the first electrode 110 connects to the conductive layer 231. Consequently, the first electrode 110 is electrically connected to the channel layer 210 of the memory transistor MTR via the conductive layer 231.

The first electrode 110 of at least one embodiment has a two-layer structure and includes an inner electrode 111 and an outer electrode 112. The inner electrode 111 is formed of amorphous silicon, for example. The outer electrode 112 is formed of titanium nitride (TiN), for example, and formed in such a way as to cover the entire outer periphery of the inner electrode 111. In place of this configuration, a configuration in which the whole of the first electrode 110 is formed of a single material may be adopted.

The dielectric layer 120 is a film formed of a high-dielectric material and is formed in such a way as to cover the entire external surface of the first electrode 110. For example, zirconium oxide, aluminum oxide or the like may be used as the high-dielectric material. The dielectric layer 120 may be a film formed of a single high-dielectric material or may be a film formed by stacking a plurality of high-dielectric materials.

The second electrode 130 is a film formed of a conductive material and is formed in such a way as to cover the entire external surface of the dielectric layer 120.

As in the case of the first electrode 110, the second electrode 130 of at least one embodiment has a two-layer structure and includes a first conductor portion 131 and a second conductor portion 132. The first conductor portion 131 is formed of the same material (TiN) as the outer electrode 112. The second conductor portion 132 is formed of the same material (amorphous silicon) as the inner electrode 111 and formed along the surface of the first conductor portion 131. The second conductor portion 132 is covered with the first conductor portion 131. In place of this configuration, a configuration in which the whole of the second electrode 130 is formed of a single material may be adopted. Moreover, the material for the second electrode 130 may be a material that is different from the material for the first electrode 110. The first conductor portion 131 is in contact with the plate electrode 150 and contains a material that is different from the material contained in the second conductor portion 132 as described above. The first conductor portion 131 corresponds to a “first portion” in at least one embodiment. The second conductor portion 132 corresponds to a “second portion” in at least one embodiment.

As shown in FIG. 2, the plate electrode 150 is placed below the memory capacitor MCP. The plate electrode 150 is provided as a wiring for adjusting the potential of the second electrode 130 of each memory capacitor MCP. The plurality of memory capacitors MCP are arranged in such a way as to lie side by side along the front surface of the plate electrode 150, and each second electrode 130 and the plate electrode 150 are electrically connected. That is, the ends of the plurality of memory capacitors MCP are common-connected to the plate electrode 150. The plate electrode 150 is formed in such a way as to extend along a plane including both the first direction and the second direction described above (a plane parallel to both directions). The plate electrode 150 corresponds to a “conductor layer” in at least one embodiment.

A portion of the upper surface of the plate electrode 150, the portion located between the memory capacitors MCP adjacent to each other, is in contact with a conductor part 131A which is a part of the first conductor portion 131. The upper surface of the conductor part 131A is in contact with a conductor part 132A which is a part of the second conductor portion 132.

The above-described configuration can be described as a configuration in which each second electrode 130 is electrically connected to the plate electrode 150 via the conductor part 131A and the conductor part 132A of the second electrode 130.

In at least one embodiment, a space SP is formed between the second electrodes 130 (the second conductor portions 132) adjacent to each other. In place of this configuration, a configuration in which the space SP is filled with a material for the second electrode 130, for example, the second conductor portion 132 may be adopted. Alternatively, a configuration in which the space SP is filled with a material that is different from the material for the second electrode 130 may be adopted.

An insulating layer 140 is formed between the lower end of the first electrode 110 and the plate electrode 150. The insulating layer 140 provides electrical insulation between the first electrode 110 and the plate electrode 150. The insulating layer 140 is in contact with both the first electrode 110 and the plate electrode 150. When viewed in the above-mentioned third direction (the direction in which the first electrode 110 extends), the insulating layer 140 has a shape corresponding to the shape of the first electrode 110 (for example, the same circular shape as the first electrode 110). The insulating layer 140 contains a material that is different from the material contained in the dielectric layer 120. For example, the dielectric constant of the material for the insulating layer 140 is lower than the dielectric constant of the material for the dielectric layer 120. Specifically, the insulating layer 140 is formed of a material containing silicon oxide, for example. The whole of the insulating layer 140 is formed as a single layer. In place of this configuration, the insulating layer 140 may be formed as a plurality of layers. The insulating layer 140 makes it possible to make longer the distance between the end of the bottom surface of the first electrode 110 and the end of the bottom surface of the second electrode 130 and prevent deterioration and a malfunction of an element which are caused by electric field concentration between the ends. The insulating layer 140 corresponds to a “first insulating layer” in at least one embodiment.

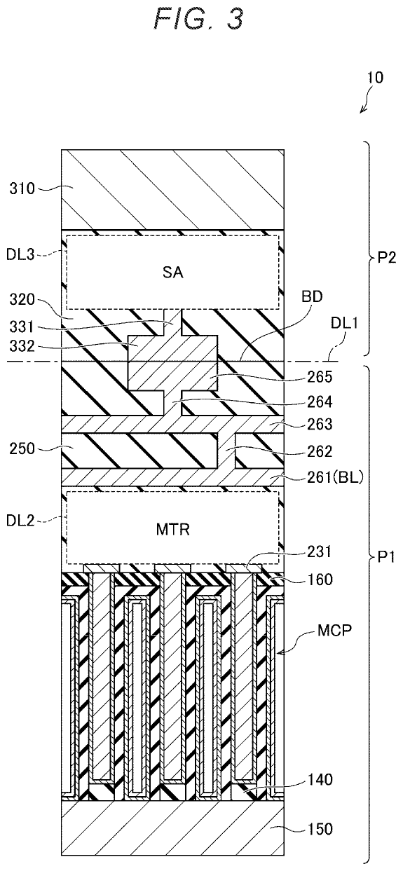

In FIG. 3, the overall configuration of the semiconductor memory device 10 including the portion shown in FIG. 2 is depicted as a schematic sectional view. A plurality of memory transistors MTR are placed in a region enclosed by a dotted line DL2 in FIG. 3; they are not concretely shown in FIG. 3.

The insulator layer 250 covering the periphery of the memory transistor MTR further extends above the wiring layer 261 (the bit line BL). A connecting pad 265 is exposed at the upper surface of the insulator layer 250, that is, a surface thereof on the side opposite to the side where the memory transistors MTR are placed. The wiring layer 261 and the connecting pad 265 are electrically connected via, for example, a via layer 262, a wiring layer 263, and a via layer 264. The connecting pad 265 corresponds to a “first pad” in at least one embodiment.

As will be described later, the semiconductor memory device 10 is produced by bonding two substrates P1 and P2 together. The substrate P1 is a portion in which the above-described memory transistor MTR, memory capacitor MCP, plate electrode 150, wiring layer 261 (bit line BL) and so forth are provided. The substrate P1 corresponds to a “second substrate” in at least one embodiment. The substrate P2 is a portion in which circuits such as a sense amplifier SA that performs, for example, reading of data from the bit line BL are provided. The substrate P2 corresponds to a “third substrate” in at least one embodiment. In FIG. 3, a region in which the circuits are provided is outlined as a region enclosed by a dotted line DL3.

The substrate P2 has a configuration in which the circuits such as the sense amplifier SA are formed on the front surface of a silicon substrate 310 and the periphery of the circuits is covered with an insulator layer 320. A connecting pad 332 is exposed at the lower surface of the insulator layer 320, that is, a surface thereof on the side opposite to the silicon substrate 310 with the circuits such as the sense amplifier SA sandwiched therebetween. The circuits such as the sense amplifier SA and the connecting pad 332 are electrically connected via, for example, a via layer 331. The connecting pad 332 corresponds to a “second pad” in at least one embodiment.

The position of the boundary between the substrate P1 and the substrate P2 is indicated by a dotted line DL1 in FIG. 3. Hereinafter, a portion where the substrate P1 and the substrate P2 are bonded together is also referred to as a “bonded portion BD”. In the bonded portion BD, the connecting pad 265 and the connecting pad 332 abut each other. This allows the wiring layer 261 (the bit line BL) and the sense amplifier SA and so forth to be electrically connected. Moreover, the plurality of memory transistors MTR are electrically connected to the circuits such as the sense amplifier SA.

As described above, in the semiconductor memory device 10 according to at least one embodiment, the circuits including the sense amplifier SA are provided and the bonded portion BD is present between the circuits and the memory transistors MTR. Moreover, the position in which the circuits are placed is the position facing the memory capacitors MCP with the memory transistors MTR sandwiched therebetween. By placing the circuits in this position, miniaturization of the semiconductor memory device 10 is achieved.

Hereinafter, a method of producing the semiconductor memory device 10 will be described.

First Sacrifice Layer Formation Process

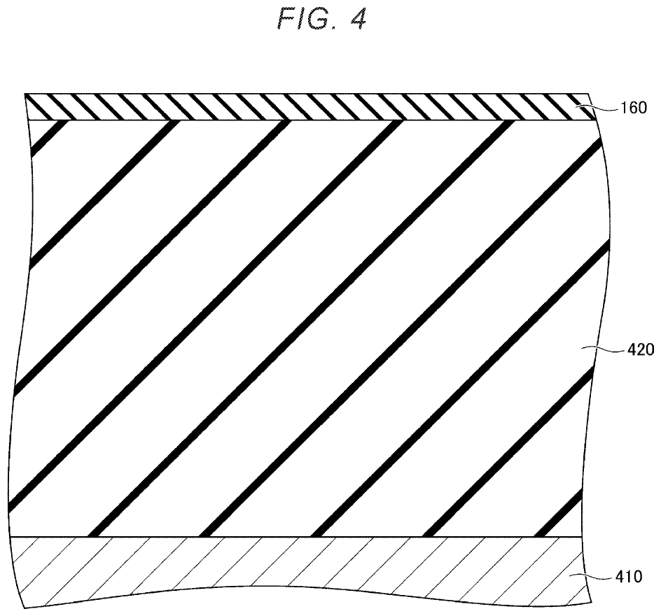

First, a sacrifice layer 420 is formed in such a way as to cover the front surface of a silicon substrate 410 which is a semiconductor substrate. In addition to the silicon substrate 410, substrates formed of various kinds of materials that can be removed in a subsequent process, such as an insulating substrate with the front surface on which a semiconductor layer such as a silicon layer is formed, may be used. For example, silicon oxide (SiO₂) is used as a material for the sacrifice layer 420. The sacrifice layer 420 corresponds to a “first sacrifice layer” in at least one embodiment. Then, an insulating layer 160 is formed in such a way as to cover the front surface of the sacrifice layer 420. For example, silicon nitride (SiN) is used as a material for the insulating layer 160. The insulating layer 160 corresponds to a “second insulating layer” in at least one embodiment. FIG. 4 shows a state in which the above-described first sacrifice layer formation process is completed.

Columnar Hole Formation Process

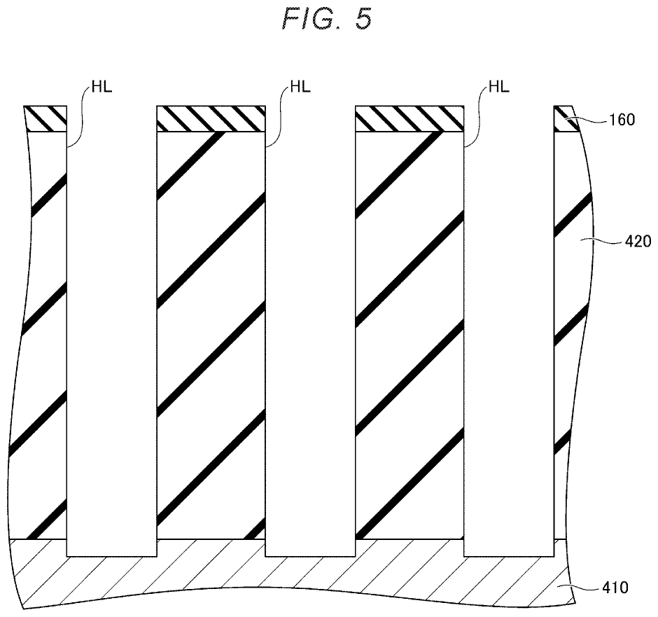

After the first sacrifice layer formation process, a columnar hole formation process is performed. In the columnar hole formation process, a plurality of columnar holes HL are formed by performing etching after masking the front surface of the insulating layer 160. FIG. 5 shows a state in which the above-described columnar hole formation process is completed.

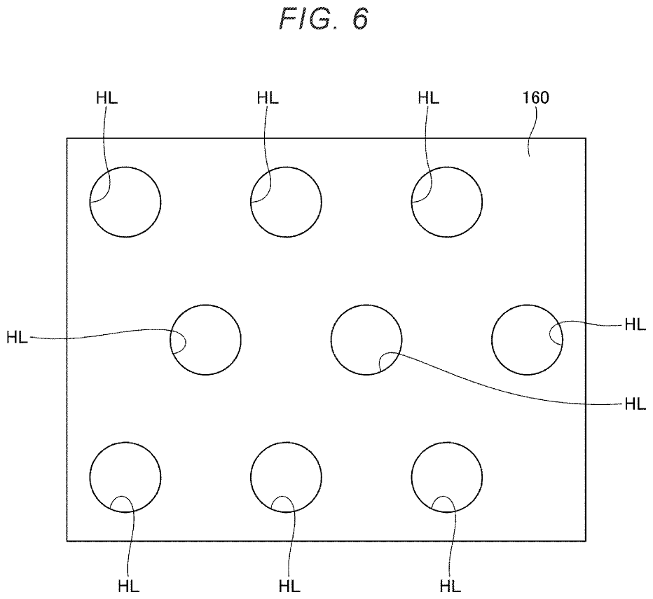

Each columnar hole HL is an approximately circular cylindrical hole and is formed from the front surface of the sacrifice layer 420 to a depth at which the columnar hole HL reaches the silicon substrate 410. In FIG. 6, a state in which the columnar holes HL are formed in the above-described manner is schematically depicted in a top view. As shown in FIG. 6, the columnar holes HL are two-dimensionally distributed with nearly uniform pitches.

Second Sacrifice Layer Formation Process

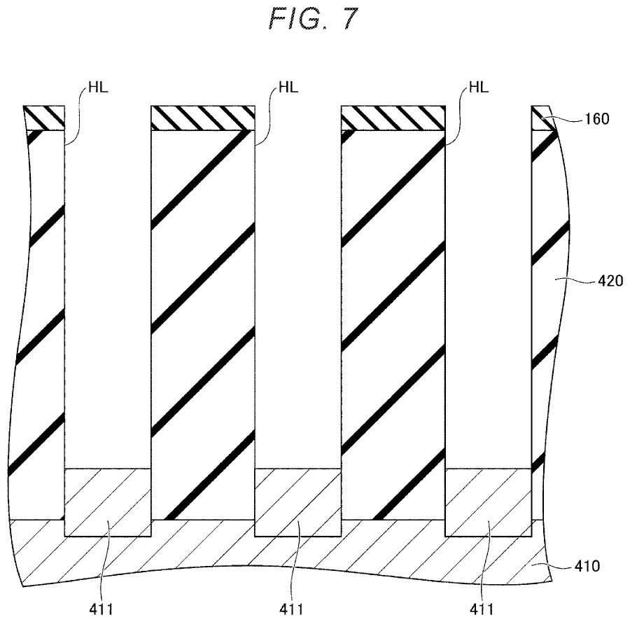

After the columnar hole formation process, a second sacrifice layer formation process is performed. In the second sacrifice layer formation process, a sacrifice layer 411 is formed in the bottom of each columnar hole HL. A material for the sacrifice layer 411 is silicon. The sacrifice layer 411 corresponds to a “second sacrifice layer” in at least one embodiment. FIG. 7 shows a state in which the second sacrifice layer formation process is completed. For example, when the silicon substrate 410 is a substrate formed of a monocrystal of silicon, the sacrifice layer 411 may be formed by epitaxial growth of silicon. The sacrifice layer 411 may be formed by selective growth of silicon. As a result of the formation of the sacrifice layer 411, the bottom surface of each columnar hole HL is located above the front surface of the silicon substrate 410 (that is, the bottom surface of each columnar hole HL is located in a position closer to the insulating layer 160 than the front surface of the silicon substrate 410).

First Electrode Formation Process

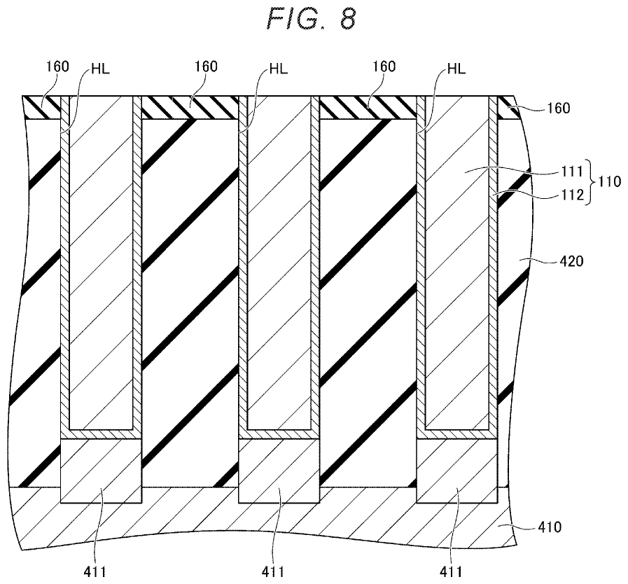

After the second sacrifice layer formation process, a first electrode formation process is performed. In the first electrode formation process, the aforementioned first electrode 110 is formed in the columnar hole HL in which the sacrifice layer 411 is formed. FIG. 8 shows a state in which the first electrode formation process is completed. The first electrode 110 may be formed by chemical vapor deposition (CVD), for example. As described earlier, the first electrode 110 of at least one embodiment has a two-layer structure. In the first electrode formation process, the outer electrode 112 is first formed and then the inner electrode 111 is formed inside the outer electrode 112. As a result of the second sacrifice layer formation process performed in advance, the sacrifice layer 411 is interposed between the lower end of the first electrode 110 and the silicon substrate 410.

Sacrifice Layer Removal Process

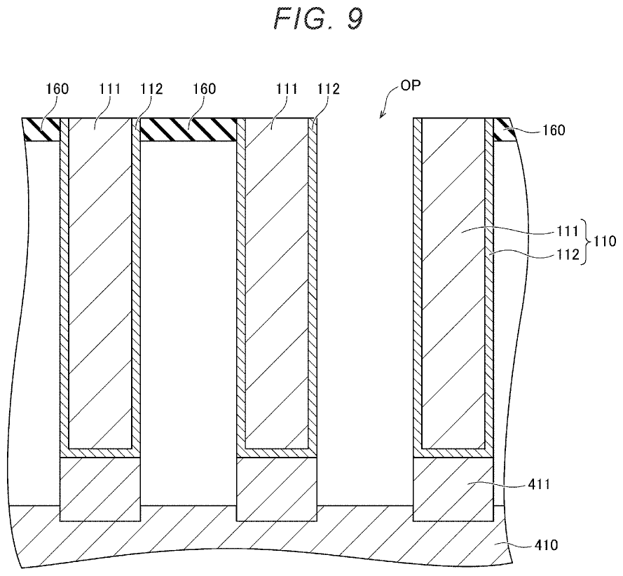

After the first electrode formation process, a sacrifice layer removal process is performed. In the sacrifice layer removal process, the sacrifice layer 420 is removed, whereby the first electrode 110 and the sacrifice layer 411 are exposed. FIG. 9 shows a state in which the sacrifice layer removal process is completed.

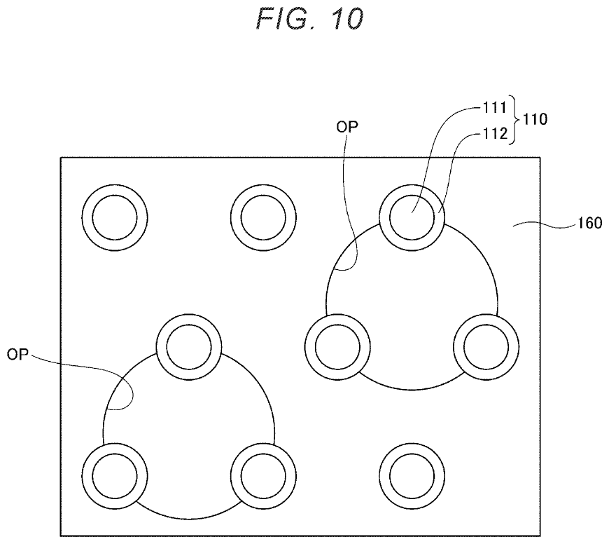

In the sacrifice layer removal process, the sacrifice layer 420 is removed by forming an opening OP in advance by removing a part of the insulating layer 160 and then performing wet etching or the like, for example, through the opening OP. In FIG. 10, a state in which the opening OP is formed in the above-described manner is schematically depicted in a top view.

As shown in FIG. 9, when the sacrifice layer 420 is removed in the sacrifice layer removal process, a plurality of columnar first electrodes 110 stand on the silicon substrate 410. In this state, the insulating layer 160 remains without being removed. Each first electrode 110 is supported by the insulating layer 160 in an upper end portion of the first electrode 110. This prevents the long and narrow first electrode 110 from being deformed and falling down. As described above, in at least one embodiment, before the columnar holes HL are formed as shown in FIG. 5, the insulating layer 160 is formed on the front surface of the sacrifice layer 420 as shown in FIG. 4. This makes it possible to prevent deformation and the like of the first electrode 110.

Dielectric Layer Formation Process and Second Electrode Formation Process

After the sacrifice layer removal process, a dielectric layer formation process and a second electrode formation process are sequentially performed. In the dielectric layer formation process, the dielectric layer 120 is formed on the entire front surface exposed in FIG. 9. As a result, the whole of the first electrode 110 and the sacrifice layer 411 is covered with the dielectric layer 120. Moreover, the upper end of the first electrode 110, the upper surface and the lower surface of the insulating layer 160 and so forth are covered with the dielectric layer 120.

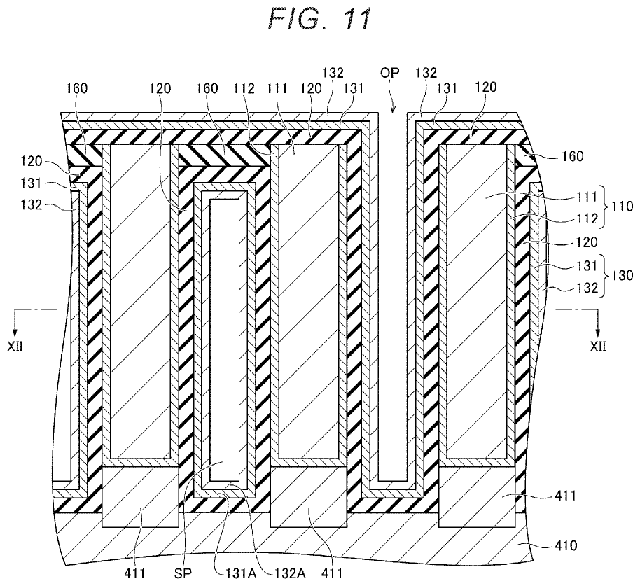

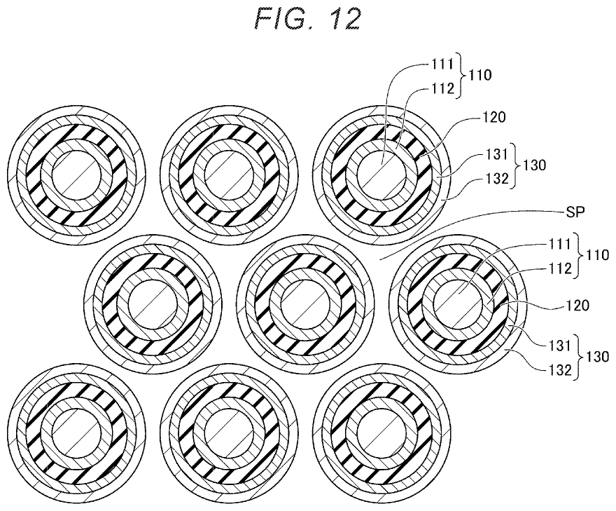

In the second electrode formation process that follows, the second electrode 130 is formed on the entire front surface of the dielectric layer 120. As described earlier, the second electrode 130 of at least one embodiment has a two-layer structure. In the second electrode formation process, the first conductor portion 131 is first formed and then the second conductor portion 132 is formed on the outside of the first conductor portion 131. As a result, the whole of the previously formed dielectric layer 120 is covered with the second electrode 130. FIG. 11 shows a state in which the dielectric layer formation process and the second electrode formation process are completed. Moreover, a cross section taken along XII-XII of FIG. 11 is shown in FIG. 12. As shown in FIGS. 11 and 12, the space SP is formed on the outside of each second electrode 130; alternatively, a configuration in which the space SP is filled with the material for the second electrode 130, for example, may be adopted as described earlier.

First Electrode Exposure Process

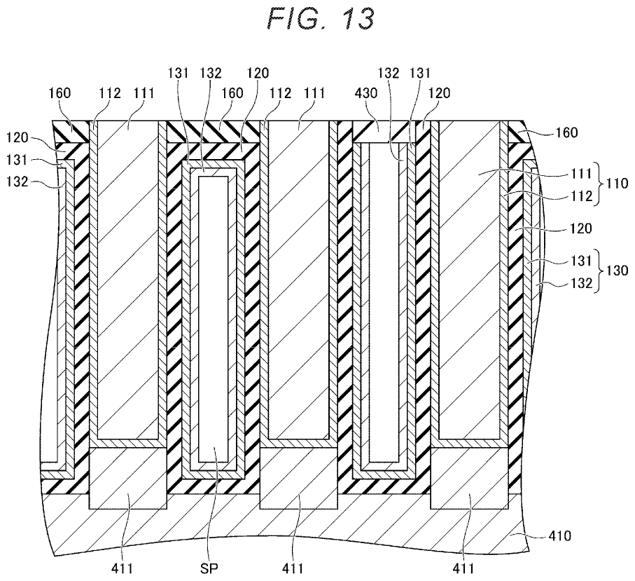

After the second electrode formation process, a first electrode exposure process is performed. In the first electrode exposure process, an end of the first electrode 110 on the side opposite to the side where the sacrifice layer 411 is located (that is, the upper end of the first electrode 110) is exposed by removing a portion above the insulating layer 160 from the state shown in FIG. 11. The first electrode exposure process may be performed by chemical mechanical polishing (CMP) or the like, for example. FIG. 13 shows a state in which the first electrode exposure process is completed. The first electrode exposure process causes the front surface of the first electrode 110 and the front surface of the insulating layer 160 to be exposed in the same plane.

In the first electrode exposure process, a recess portion tends to be formed in the front surface in a portion around the first electrode 110 where the opening OP was formed in FIG. 11. To address this, after the first electrode exposure process, it is preferable to fill the recess portion with an insulating material 430 and planarize the entire front surface again as shown in FIG. 13.

Transistor Formation Process

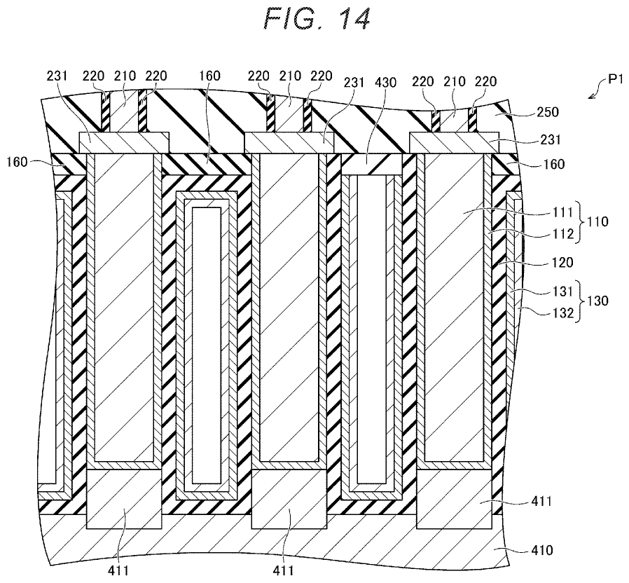

After the first electrode exposure process and the subsequent filling of the insulating material 430, a transistor formation process is performed. In the transistor formation process, the conductive layer 231, the memory transistor MTR, the wiring layer 261 (the bit line BL), the connecting pad 265 that is electrically connected to the memory transistor MTR, the insulator layer 250 that covers them, and so forth are formed above the first electrode 110. That is, a portion of the substrate P1 shown in FIG. 3, the portion above the memory capacitor MCP, is formed. Each memory transistor MTR thus formed is electrically connected to the first electrode 110. Since publicly known various methods may be adopted as a specific method of forming the memory transistor MTR and so forth above the first electrode 110, specific explanations thereof are omitted. FIG. 14 shows a part of a state in which the transistor formation process is completed.

Bonding Process

After the transistor formation process, a bonding process is performed. In the bonding process, the substrate P2 on which the circuits including the sense amplifier SA and the connecting pad 332 connecting to the circuits are formed in advance and the substrate P1 in the above-described state are bonded together as shown in FIG. 3. This bonding is performed in such a way that the connecting pad 265 and the connecting pad 332 abut each other. As a result, the substrate P1 and the substrate P2 are integrated into one piece with the bonded portion BD located therebetween. The plate electrode 150 shown in FIG. 3 is not formed at this point. Since publicly known various methods may be adopted as a specific method of forming the substrate P2, specific explanations thereof are omitted.

Silicon Layer, Etc. Removal Process

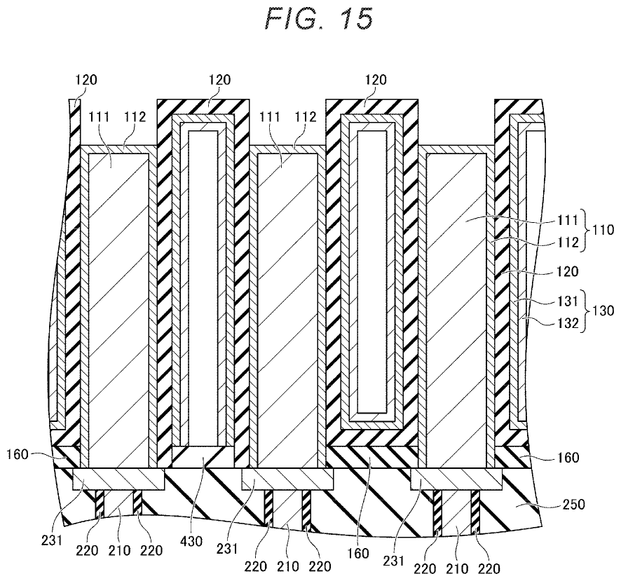

After the bonding process, a silicon layer, etc. removal process is performed. In the silicon layer, etc. removal process, after the substrate P1 integrated with the substrate P2 is turned upside down from the state shown in FIG. 14, the whole of the silicon substrate 410 and the sacrifice layer 411 which are located on the upper side is removed. The removal of the silicon substrate 410 and so forth may be performed by CMP, dry etching, or wet etching. FIG. 15 shows a state in which the silicon layer, etc. removal process is completed.

Insulating Layer Formation Process

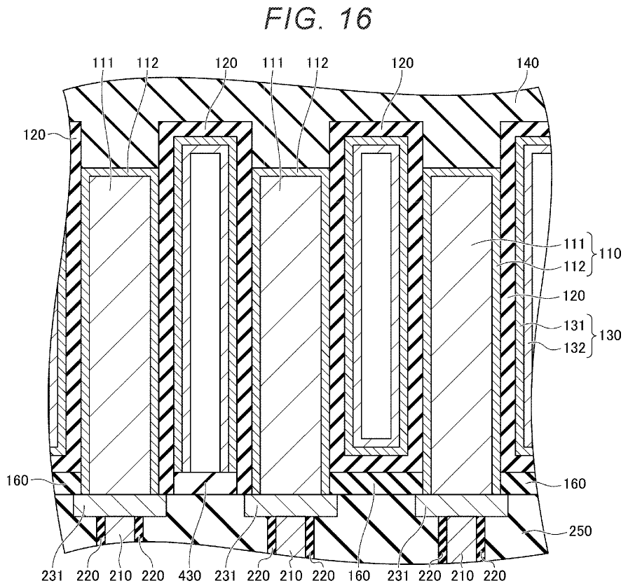

After the silicon layer, etc. removal process, an insulating layer formation process is performed. In the insulating layer formation process, the insulating layer 140 is formed in such a way as to cover the entire front surface including the portion where the sacrifice layer 411 was formed. FIG. 16 shows a state in which the insulating layer formation process is completed.

Second Electrode Exposure Process

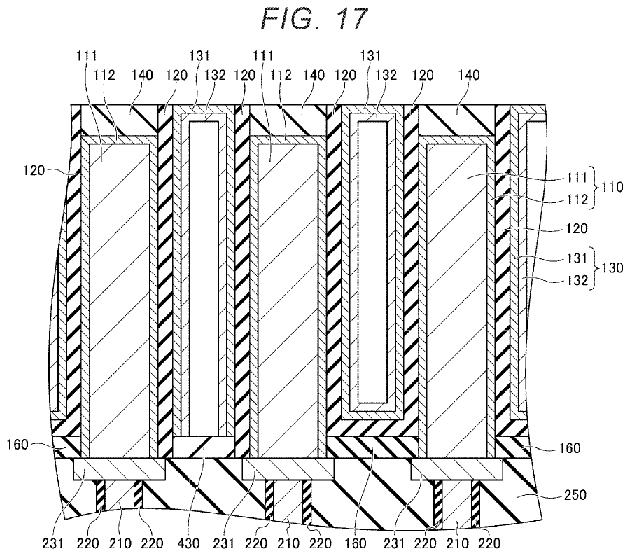

After the insulating layer formation process, a second electrode exposure process is performed. In the second electrode exposure process, the second electrode 130 (specifically, the first conductor portion 131) is exposed around the insulating layer 140 by removing a part of the insulating layer 140 from the front surface side from the state shown in FIG. 16. The second electrode exposure process may be performed by CMP or the like, for example. FIG. 17 shows a state in which the second electrode exposure process is completed.

A portion of the second electrode 130, the portion extending parallel to the front surface of the silicon substrate 410 (an upper end portion in FIG. 17), is not removed in the second electrode exposure process and is exposed at the front surface together with the insulating layer 140. Thus, when the second electrode 130 is exposed around the insulating layer 140, the second electrodes 130 are continuously connected along the front surface at which they are exposed. A portion of the second electrode 130 which is exposed as described above is a portion which will become the conductor part 131A and the conductor part 132A described earlier with reference to FIG. 2.

Plate Electrode Formation Process

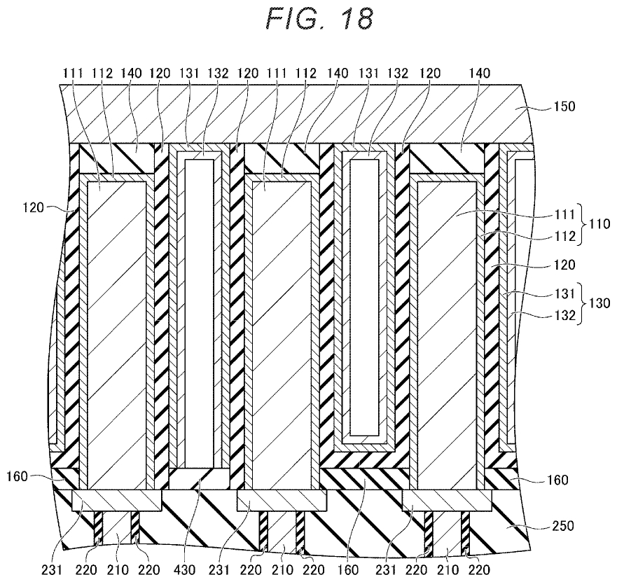

After the second electrode exposure process, a plate electrode formation process is performed. In the plate electrode formation process, the plate electrode 150 is formed in such a way as to cover the whole of the second electrode 130 exposed as described above and the insulating layer 140. For example, tungsten (W) is used as a material for the plate electrode 150. FIG. 18 shows a state in which the plate electrode formation process is completed. At this point, the plate electrode 150 covers each insulating layer 140 and is electrically connected to the exposed second electrode 130. The plate electrode 150 and the first electrode 110 are electrically insulated because the insulating layer 140 formed of an insulating material is interposed therebetween.

After the plate electrode formation process, etching and the like for making the plate electrode 150 have a predetermined wiring shape are performed, and the semiconductor memory device 10 with the configuration shown in FIG. 3 is completed.

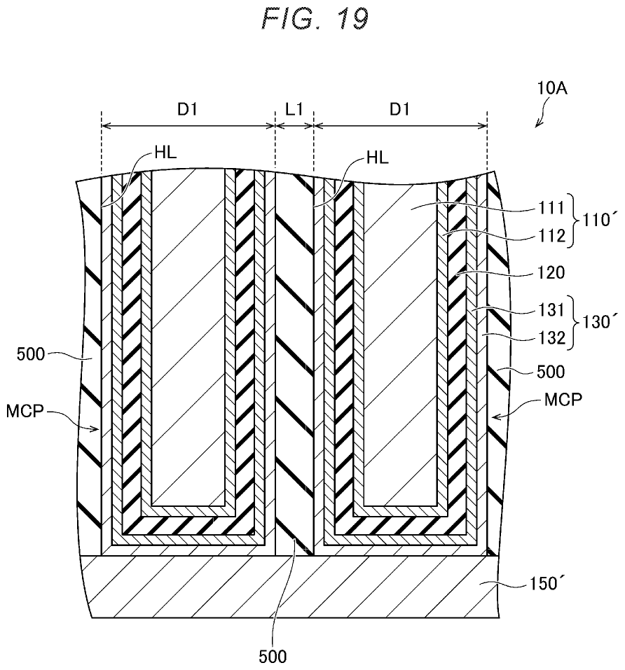

In FIG. 19, the configuration of a semiconductor memory device 10A according to a comparative example is shown as a schematic sectional view. In FIG. 19, a dash (′) is put after a reference sign denoting each portion of FIG. 2 and the reference sign with a dash is used as a reference sign denoting a portion corresponding to each portion of FIG. 2. This comparative example has a configuration in which a memory capacitor MCP having the same configuration as the present embodiment is embedded in an insulating layer 500 formed of silicon oxide (SiO₂), for example. As in the case of the present embodiment, also in this comparative example, an unillustrated memory transistor MTR is provided above the memory capacitor MCP.

In a configuration in which the plate electrode 150, the memory capacitor MCP, and the memory transistor MTR are provided in order from below as in this comparative example, a production method in which the plate electrode 150, the memory capacitor MCP, and the memory transistor MTR are formed in order from the plate electrode 150 located on the lower side may be adopted. In this case, the insulating layer 500 is first formed in such a way as to cover the plate electrode 150, a columnar hole HL is formed in the insulating layer 500, and then a first conductor portion 131 and so forth are formed in order on the inner surface of the columnar hole HL.

In FIG. 19, the inside diameter of the columnar hole HL is denoted by “D1”. Moreover, the distance between the columnar holes HL adjacent to each other is denoted by “L1”.

It is preferable to reduce each of D1 and L1 to miniaturize the semiconductor memory device 10A. However, when the long and narrow columnar holes HL are formed, D1 tends to be increased in a part in a height direction. This makes it necessary to allow a certain distance for L1 to prevent the columnar holes HL adjacent to each other from being continuously connected to each other.

Moreover, in the production method of this comparative example, it is necessary to form the first conductor portion 131 and so forth in order from the inner surface of the columnar hole HL toward the center, which makes it necessary to allow a certain length for D1. For these reasons, it is difficult to reduce each of D1 and L1 in this comparative example.

In contrast to this, in the semiconductor memory device 10 according to the present embodiment, only the first electrode 110 is formed in the columnar hole HL and then the dielectric layer 120 and the second electrode 130 are formed on the outer periphery of the first electrode 110. There is no need to form the whole of the memory capacitor MCP in the columnar hole HL, which makes it possible to make the inside diameter D1 of the columnar hole HL smaller than that of the comparative example. Since each of L1 and D1 can be minimized, it is possible to miniaturize the whole of the semiconductor memory device 10 more easily than the comparative example described above.

While the embodiments have been described with reference to specific examples, the disclosure is not limited to these specific examples. Any modification obtained by a person skilled in the art by appropriately making a design change to any of these specific examples is also included in the scope of the disclosure as long as it has a feature of the disclosure. The elements of the above specific examples and the arrangement, conditions, shapes, and the like thereof are not limited to those illustrated above and may be changed as appropriate. The combination of the elements of the above specific examples may be changed as appropriate unless a technical contradiction arises.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor memory device comprising:
a conductor layer extending along a plane, the plane including a first direction and a second direction intersecting the first direction;
a plurality of capacitors arranged along a front surface of the conductor layer; and
a plurality of transistors electrically connected to the plurality of capacitors,
wherein each capacitor includes:
a columnar first electrode extending in a third direction, the third direction crossing each of the first direction and the second direction, the columnar first electrode electrically connected to one of the plurality of transistors;
a dielectric layer disposed on an outer periphery of the first electrode;
a second electrode disposed on an outer periphery of the dielectric layer, the second electrode electrically connected to the conductor layer; and
an insulating layer disposed between the first electrode and the conductor layer, the insulating layer containing a material different from a material contained in the dielectric layer.

2. The semiconductor memory device according to claim 1,
wherein the insulating layer is in contact with the first electrode and the conductor layer.

3. The semiconductor memory device according to claim 2,
wherein the insulating layer contains silicon oxide.

4. The semiconductor memory device according to claim 1,
wherein the insulating layer and the first electrode have substantially the same shape when viewed from the third direction.

5. The semiconductor memory device according to claim 1,
wherein the second electrode includes a first portion and a second portion, the second portion covered with the first portion and in contact with the conductor layer, the second portion containing a material different from a material contained in the first portion.

6. The semiconductor memory device according to claim 1,
wherein a cross section of the first electrode perpendicular to the third direction has a circular shape.

7. The semiconductor memory device according to claim 1,
wherein the transistor includes a channel layer containing an oxide semiconductor.

8. The semiconductor memory device according to claim 1, further comprising:
circuits, including a sense amplifier, disposed on a substrate,
wherein the plurality of transistors are electrically connected to the circuits.

9. The semiconductor memory device according to claim 8,
wherein the plurality of transistors are disposed between the circuits and the plurality of capacitors.

10. A method of producing a semiconductor memory device comprising:
forming a first sacrifice layer on a front surface of a first substrate;
forming, in the first sacrifice layer, a columnar hole reaching the first substrate;
forming a second sacrifice layer in the columnar hole;
forming a first electrode in the columnar hole having the second sacrifice layer;
exposing the first electrode and the second sacrifice layer by removing the first sacrifice layer;
forming a dielectric layer covering an outside of the first electrode and the second sacrifice layer;
forming a second electrode covering an outside of the dielectric layer;
forming a transistor electrically connected to the first electrode;
removing the first substrate and the second sacrifice layer;
forming a first insulating layer in a portion where the second sacrifice layer was formed;
exposing the second electrode around the first insulating layer; and
forming a conductor layer that covers the first insulating layer, the conductor layer being electrically connected to the second electrode.

11. The method of producing a semiconductor memory device according to claim 10, further comprising:
exposing an end of the first electrode on a side opposite to the second sacrifice layer after forming the second electrode.

12. The method of producing a semiconductor memory device according to claim 11, further comprising:
filling a recess portion around the first electrode with an insulating material after exposing the end of the first electrode.

13. The method of producing a semiconductor memory device according to claim 10, further comprising:
forming a second insulating layer on a front surface of the first sacrifice layer before forming the columnar hole.

14. The method of producing a semiconductor memory device according to claim 13, further comprising:
forming an opening in the second insulating layer; and
removing the first sacrifice layer through the opening.

15. The method of producing a semiconductor memory device according to claim 10, further comprising:
before removing the first substrate and the second sacrifice layer, bonding together a second substrate and a third substrate, the second substrate including the first substrate and the transistor, the third substrate having thereon circuits including a sense amplifier.

16. The method of producing a semiconductor memory device according to claim 15, further comprising:
forming a first pad in the second substrate, the first pad being electrically connected to the transistor;
forming a second pad in the third substrate, the second pad being electrically connected to the circuits; and
performing bonding such that the first pad and the second pad abut each other.

17. The semiconductor memory device according to claim 1,
wherein the columnar first electrode includes an inner electrode and an outer electrode, the outer electrode being outside of the inner electrode and being of a material different from that of the inner electrode.

18. The semiconductor memory device according to claim 17, wherein the inner electrode is of an amorphous silicon material.

19. The semiconductor memory device according to claim 18, wherein the outer electrode is of a titanium nitride material.

20. The semiconductor memory device according to claim 5,
wherein the second portion is of an amorphous silicon material.
